(19) United States
(12) Patent Application Publication
(10) Pub. No.: US 2010/0273307 A1
(43) Pub. Date: Oct. 28, 2010

(54) METHOD OF MAKING A DEVICE INCLUDING A CAPACITIVE STRUCTURE

(75) Inventors: Stefan Sedlmaier, Muenchen (DE); Wolfgang Lehnert, Lintach (DE); Klemens Pruegl, Regensburg (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AG, Neubiberg (DE)

(21) Appl. No.: 12/430,594

(22) Filed: Apr. 27, 2009

(51) Int. Cl. H01L 21/02

(52) U.S. Cl. 438/394; 257/E21.008

(57) ABSTRACT

A method for making a device including a capacitive structure is disclosed. One embodiment provides a carrier layer having a surface. A first dielectric layer is formed on the surface. A silicon layer including silicon grains is formed on the first dielectric layer using a deposition process. A second dielectric layer is formed on the second silicon layer. A layer of an electrically conductive material is formed on the dielectric layer. A temperature process for heating at least the first dielectric layer is performed. The temperature and duration of the temperature process is selected such that the first dielectric layer is modified so that the silicon layer is electrically connected to the carrier layer.

### BACKGROUND

The present disclosure relates to an integrated device including a capacitive structure and in one embodiment to a method for producing a capacitive structure.

Known methods for producing integrated capacitive structures include forming a layer of hemispherical silicon grains (HSG) on a semiconductor substrate, forming a dielectric layer on the HSG layer, and forming a conductive layer on the dielectric layer. In the capacitive structure resulting from this method the semiconductor substrate and the HSG layer together form a first electrode, and the conductive layer forms a second electrode. Forming an HSG layer and forming the dielectric layer on the HSG layer instead of directly forming the dielectric layer results in a capacitive structure having an increased capacitance. The capacitance is dependent on the surface area of the dielectric layer, where this surface area is larger if the dielectric layer is applied to the HSG layer, because the HSG layer has an increased surface area as compared to the surface area of the underlying substrate.

However, with conventional methods the grain size of the silicon grains in the HSG layer is limited to about 60 nm. Further, the grains may overlap with each other. This limits the surface area of the HSG layer and, therefore, the capacitance of the resulting capacitive structure.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIGS. 1A-1F illustrate one embodiment of a method for producing a device including a capacitive structure.

FIGS. 2A-2E illustrate one embodiment of a method for producing a capacitive structure.

FIG. 3 illustrates a power semiconductor component including a capacitive structure, the capacitive structure having been produced in accordance with the method according to FIG. 2.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

One embodiment provides a method for producing a device including a capacitive structure. The method includes providing a carrier layer having a surface. A first dielectric layer is formed on the surface. A silicon layer including silicon grains is formed on the first dielectric layer using a deposition process. A second dielectric layer is formed on the second silicon layer. A layer of an electrically conductive material is formed on the dielectric layer. The method further includes performing a temperature process for heating at least the first dielectric layer, temperature and duration of the temperature process being selected such that the first dielectric layer is modified so that the silicon layer is electrically connected to the carrier layer.

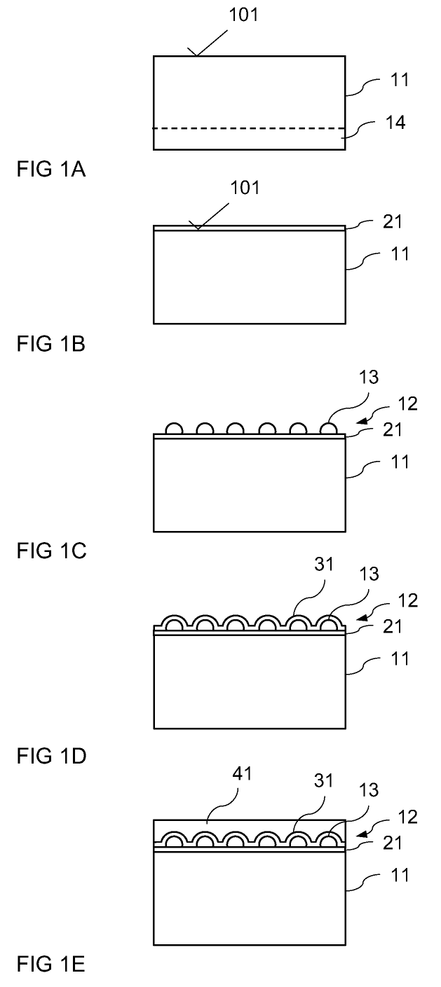

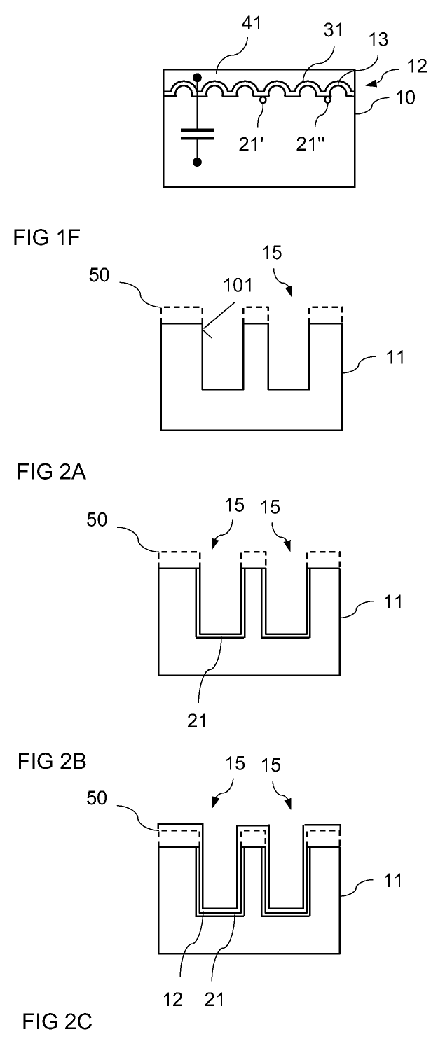

FIGS. 1A to 1F illustrate one embodiment of a method for producing a device including a capacitive structure. Referring to FIG. 1A, in a first method process a carrier layer 11 having a surface 101 is provided. The carrier layer 11 may be any carrier layer suitable for producing an integrated capacitive structure. According to one example carrier layer 11 is a semiconductor layer deposited on a semiconductor substrate 14 (illustrated in dashed lines in FIG. 1A) or is a semiconductor substrate itself. Carrier layer 11 is, for example, a silicon layer, where the silicon material may be a monocrystalline silicon, a polycrystalline silicon or an amorphous silicon. However, the carrier layer may be comprised of any other suitable semiconductor material or any other electrically conducting material.

Referring to FIG. 1B, in a next process a first dielectric layer 21 is formed on the surface 101 of carrier layer 11. First dielectric layer 21 is, for example, an oxide layer or a nitride layer 21. An oxide layer as first dielectric layer 21 can be formed by depositing an oxide layer on the surface 101 or by performing a temperature process that oxidizes the surface 101, thereby forming an oxide layer. A nitride layer as first dielectric layer 21 is, for example, formed using a deposition process.

The first dielectric layer 21 is a relatively thin layer having a thickness of for example, between 0.5 nm and 5 nm. The thickness of the first dielectric layer is in one embodiment less than 3 nm, or even less than 1 nm. In case first dielectric layer 21 is an oxide layer this layer may include native oxide that is formed, if surface 101 is subject to an oxidizing atmosphere, i.e., an oxygen containing atmosphere, at room temperature.

First dielectric layer 21 is an auxiliary layer that is required for a deposition process that will be explained with reference to FIG. 1C but that is not required in the capacitive structure that is to be produced. Generally, first dielectric layer 21, therefore, should be as thin as possible.

Referring to FIG. 1C a silicon layer 12 that includes silicon grains 13 is deposited on the first dielectric layer 21. Depositing the first silicon layer 12 may be performed using a chemical vapor deposition (CVD) process in which silicon is deposited from a gaseous silicon source, which is also referred to as precursor. In one embodiment, the deposition process is a low pressure chemical vapor deposition process (LPCVD) that is performed in a usual process chamber, like a chamber that is used for epitaxially growing silicon on a carrier layer, or like a furnace tube. In one process according to the present disclosure the silicon is epitaxially grown in grains on the first dielectric layer 21. The deposition process according to one embodiment is a semi-selective deposition process that allows silicon to be deposited on the first dielectric layer, while in a selective deposition process silicon would only be deposited on a silicon layer but not on a dielectric layer. Semi-selectivity of the process is obtained by using a gaseous silicon source (precursor) that includes chlorine (Cl). In one embodiment, this gaseous silicon source is dichlorosilane (DCS, SiH₂Cl₂), trichlorosilane (TCS, SiHCl₃), or silicon tetrachloride (SiCl₄). Besides the use of a chlorine containing gaseous silicon source semi-selectivity of the deposition process can be obtained by adding an etching gas to the silicon source. In on embodiment, this etching gas is hydrogen chloride (HCl) gas. Besides the precursor and the etching gas a carrier gas is used in the deposition process. In one embodiment, the carrier gas is hydrogen (H₂).

In the following two examples, process parameters for a semi-selective deposition process, that is suitable for producing a silicon layer that includes silicon grains, will be explained.

### EXAMPLE 1

| | |
|---|---|
| Precursor: | DCS (flow rate between 0.01 slpm and 1 slpm) |
| Etching gas: | HCl (flow rate between 0 and 0.5 slpm) |
| Carrier gas: | H₂ (flow rate 10-100 slpm) |
| Pressure: | between 1 Torr (≈133,322 Pa) and 100 Torr, |
| | in particular between 5 Torr and 30 Torr |
| Deposition time: | between 10 s (seconds) and 600 s, in particular |
| | between 10 s and 100 s |
| Temperature: | between 600° C. and 1250° C., in particular |
| | between 750° C. and 1000° C. |

### EXAMPLE 2

| | |
|---|---|
| Precursor: | TCS (flow rate between 0.1 slpm and 10 slpm) |
| Etching gas: | HCl (flow rate between 0 and 5 slpm) |
| Carrier gas: | H₂ (flow rate 10-100 slpm) |
| Pressure: | about atmosphere pressure (760 Torr = 1,013 bar) |
| Deposition time: | between 10 s (seconds) and 600 s, in particular |
| | between 10 s and 100 s |
| Temperature: | between 600° C. and 1250° C., in particular |
| | between 750° C. and 1000° C. |

In these examples “Pressure” and “Temperature” are the pressure and the temperature in the process chamber, in which the deposition process is performed. “Deposition time” is the time for which the deposition process is performed. Further, the unit 1 slpm, that is commonly used in the field of vacuum technique, being 1.68875 Pa·m³/s.

The semi-selective deposition process results in the silicon layer 12 having silicon grains 13, where an average diameter of the silicon grains and an average distance between neighboring silicon grains may be adjusted by proper selection of the following process parameters during the deposition process: gas flow of the process gasses, like the gaseous silicon source and the etching gas; temperature during the deposition process; and pressure during the deposition process. According to one embodiment these process parameters are selected to result in silicon grains having an average diameter of more than 40 nm, in one embodiment more than 70 nm, and an average mutual distance of about 120 nm. In a specific example an average diameter of the silicon grains is about 300 nm and an average mutual distance is about 200 nm. This may be obtained using a deposition process having the following parameters:

| | |
|---|---|
| Precursor: | DCS (flow rate 0.2 slpm) |
| Etching gas: | HCl (flow rate between 0 slpm) |
| Carrier gas: | H₂ (flow rate 25 slpm) |
| Pressure: | 15 Torr |
| Deposition time: | 60 s |
| Temperature: | 900° C. |

In one process illustrated in FIG. 1D a second dielectric layer 31 is formed on the silicon grains 13 of the silicon layer 12 and on those parts of the first dielectric layer 31 that are not covered by the silicon grains 13. In one embodiment, the second dielectric layer 31 is an oxide layer that is formed by a deposition or oxidation process. An oxide that is obtained using a deposition process may be a semiconductor oxide or a metal oxide, the latter being, for example, an aluminum oxide. An oxide that is obtained by an oxidation process is a silicon oxide. However, the second dielectric layer 31 may be any other dielectric layer that is suitable to be used in a capacitive structure, like a nitride, or a high-k-dielectric. The dielectric layer 31 may also be realized as a layer stack that includes two or more dielectric layers, with each of these layers including one of the mentioned dielectric materials.

Besides other parameters, like thickness of the second dielectric layer 31 and the dielectric properties of the second dielectric layer 31, the surface area of the second dielectric layer 31 influences the capacitance of the capacitive structure to be produced. This surface area increases with increasing diameter of the silicon grains 13. An example for obtaining a maximum surface area of the dielectric layer, will now be explained for the case in which the dielectric layer 31 is a deposited layer, or is a layer stack in which the first layer is a deposited layer: For a given diameter of the silicon grains 13 a maximum of the surface area is obtained if an (average) distance of the silicon grains 13 is about twice, or slightly more than twice, the thickness of the second dielectric layer 31. Starting from this distance, that results in a maximum of the surface area, the surface area decreases with decreasing distance between the individual silicon grains 13, and decreases with increasing distance between the individual silicon grains 13. The semi-selective deposition process that has been explained above allows to adjust the diameter of the silicon grains 13 and to adjust the mutual distance of the silicon grains 13 by proper selecting the deposition process parameters. Considering the desired thickness of the second dielectric layer 31 these process parameters may, therefore, be selected such to result in large silicon grains 13, i.e., silicon grains having a diameter of more than 40 nm or even more than 60 nm, and having a mutual distance that is about twice the thickness of the second dielectric layer 31, thereby obtaining a maximum surface area of the second dielectric layer 31, and thereby obtaining a maximum capacitance of the resulting capacitive structure for a given surface area of surface 101.

If the dielectric layer 31 is an oxide layer or has an oxide layer as the first layer, and if this oxide layer is a thermal oxide, i.e., has been produced using a thermal process, the mutual distance between neighboring grains may be smaller than half the thickness of the dielectric layer 31 in order to obtain a maximum surface area.

Referring to FIG. 1E an electrically conductive layer 41 is formed on the second dielectric layer 31. This conductive layer 31 is, for example, but is not limited to, a doped polycrystalline semiconductor layer, like a layer of n-doped polysilicon.

The method further includes performing a temperature process for heating-up at least the first dielectric layer 21. Temperature and duration of this temperature process are selected such that the first dielectric layer is modified, resulting in the silicon layer 12 or silicon grains 13, respectively, being electrically connected to the carrier layer 11. FIG. 1F schematically illustrates the capacitive structure after this temperature process has been formed. Silicon layer 12 with the silicon grains 13 and carrier layer 11 together form a first electrode 10 of the capacitive structure, the second dielectric layer 31 forms a capacitor dielectric of the capacitive structure, and conductive layer 41 forms a second electrode of the capacitive structure. For a better understanding, the electrical symbol of the capacitor structure is also illustrated in FIG. 1F.

Referring to the illustration in FIGS. 1E and 1F the temperature process for modifying the first dielectric layer 21 is performed after the conductive layer 41 has been formed. However, this is only an example, the method is not limited to performing this temperature process after forming conductive layer 41. Rather, this temperature process may be performed any time after the second dielectric layer 31 has been formed. In case the second dielectric layer 31 is formed using a thermal oxidation process this oxidation process itself may be the temperature process for modifying the first dielectric layer 21. During the temperature process different kinds of modifications of the first dielectric layer 21 may occur, where each of these modifications results in breaking-up the first dielectric layer 12, thereby resulting in an electrical connection between the silicon grains 13 and the carrier layer 11. For the example of an oxide layer as the first dielectric layer 21 two different kinds of possible modifications under the influence of the temperature process will shortly be explained. First, oxide molecules—i.e., silicon dioxide molecules, if the oxide layer is a silicon oxide layer—agglomerate to pearl-like structures in the interface region between carrier layer 11 and silicon layer 12. Such an agglomeration 21′ of oxide molecules is schematically illustrated in FIG. 1F. Second, the oxide molecules of oxide layer 21, under the influence of the temperature during the temperature process, may dissociate in their components, i.e., oxygen and semiconductor atoms, like silicon atoms, if oxide layer 21 is a silicon oxide layer. The oxygen atoms resulting from this dissociation of the oxide molecules may agglomerate or may form oxygen precipitates 21″ in the carrier layer 11 or in the interference region between carrier layer 11 and silicon layer 12. Further, at least a part of the oxygen atoms may “dissolve” inside the silicon crystal lattice.

Similar mechanisms do apply to a nitride layer as the first dielectric layer 21. A thin layer having a thickness of, for example, less than 1 nm, may also be “dissolved” under the influence of the temperature process.

The temperature of the temperature process for modifying or dissolving the first dielectric layer is, for example, between 700° C. and 1300° C., in one embodiment between 800° C. und 1300° C., and more particular in one embodiment between 900° C. und 1250° C. The duration of the temperature process is, for example, between 5 s to 15 h, in one embodiment between 1 min to 300 min, and more particular in one embodiment between 5 min to 200 min.

Even in those cases in which the first dielectric layer 21 has a thickness that is not or that is not completely dissolved, so that a thin layer of less than 3 nm, in one embodiment less than 1 nm, remains after the temperature process has been performed, a proper functionality of the capacitive structure may still be ensured. By applying an electrical voltage between the first electrode 10 and the second electrode 41 charge carriers from the substrate may tunnel through the remaining first dielectric layer into the silicon grains, or may tunnel through the remaining first dielectric layer from the grains into the substrate. In this case the silicon layer 12 including the grains 13 and the underlying substrate 11 are contacted to one another via a “tunnel contact”.

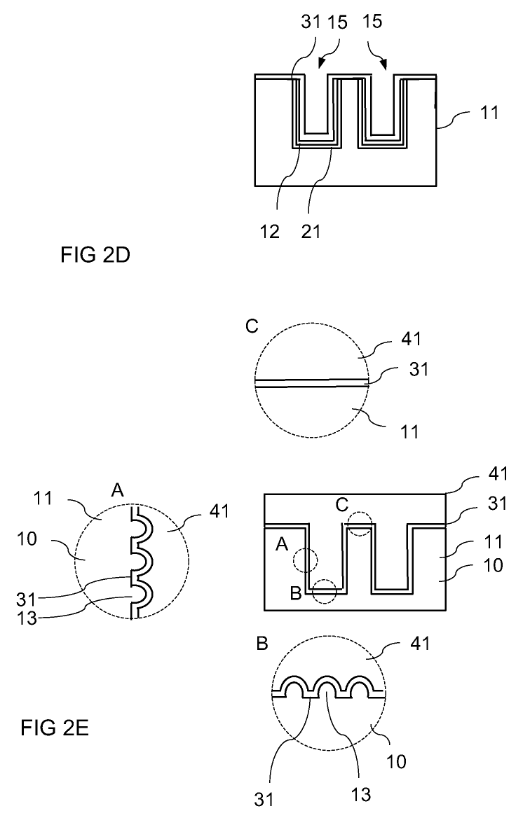

In the method that has been explained with reference to FIG. 1, the layer stack including the first dielectric layer 21, silicon layer 12, second dielectric layer 31 and conductive layer 41 is formed on a planar horizontal surface of carrier layer 11. However, this is only an example. This layer stack may be formed on any surface of carrier layer 11, in one embodiment, on surfaces of trenches that are formed in carrier layer 11. A method for forming a capacitive structure in trenches of carrier layer 11 will be explained with reference to FIGS. 2A through 2E.

Referring to FIG. 2A carrier layer 11 includes at least one (two in the example) trench 15 that extend into carrier layer 11. In the example according to FIG. 2A these trenches 15A extend in a vertical direction of carrier layer 11. However, these trenches may also extend under an angle other than 0° as compared to the vertical direction into the carrier layer 11. Trenches 15 may be produced using a conventional method for forming trenches in the carrier layer 11, including an etching process using an etching mask 50, like a hard mask. The surface of the carrier layer 11 after forming the trenches 15 includes sidewalls and bottoms of the trenches 15, as well as horizontal surfaces on top of mesa regions, where these mesa regions are semiconductor regions of carrier layer 11 that are between two neighboring trenches or adjacent to the trenches. Optionally the etching mask 50 is left on the surfaces of these mesa regions after trench etching (as illustrated in dashed lines in FIG. 2A). Mask 50 is, for example, an oxide hard mask.

The processes after having formed trenches 15 in carrier layer 11 correspond to the processes that have been explained with reference to FIGS. 1A to 1F. Referring to FIG. 2B these processes include forming the first dielectric layer 21 on the surface of carrier layer 11. In case the etching mask 50 is present on the top surfaces of the mesa region, the first dielectric layer 21 is only formed on sidewalls and the bottom of the trenches, if the etching mask 50 is an oxide mask and if the first dielectric layer 21 is formed by thermal oxidation.

If the first dielectric layer 21 is formed by a deposition process, dielectric layer 21 is deposited on the sidewalls and the bottom of the trenches 15, and as well on the surfaces of the etching mask 50 (not illustrated in FIG. 2). Concerning forming the first dielectric layer 21 the explanations that have been made with reference to FIG. 1B apply accordingly.

Referring to FIG. 2C the silicon layer 12 including the silicon grains is deposited on the first dielectric layer 21 using the semi-selective deposition process that has been explained above. In FIG. 2C silicon layer 21 is illustrated only schematically, the silicon grains 23 are not explicitly illustrated in this figure. During this semi-selective deposition process silicon grains may also be formed on the etching mask 50. This is true, if the etching mask 50 is made of a material, like an oxide or a nitride, that allows for deposition of silicon grains, if the explained semi-selective deposition process is applied.

If the etching mask 50 has been left on the top surfaces of the mesa regions, this mask 50, together with sections of the silicon layer 12 and the dielectric layer 21 that have been formed on the etching mask 50, may be removed, before second dielectric layer 31 is formed in next processes. FIG. 2D schematically illustrates the semiconductor structure after removing protection layer 50 and forming second dielectric layer 31. Second dielectric layer 31 is formed on the top surfaces of the mesa regions as well as on the silicon layer 12 on the side walls and the bottoms of trenches 15.

In next processes conductive layer 41 is formed in the trenches 15 and above the top surfaces of mesa region. Conductive layer 41 may completely fill the trenches, as illustrated in FIG. 2E, or may be formed such that it only covers the second dielectric layer 31 but does not completely fill the trenches (not illustrated).

A and B in FIG. 2E are details of the capacitive structure in a region of the sidewall of one of the trenches (detail A) and the bottom of one of the trenches (detail B). In these regions a first electrode 10 of the capacitive structure includes carrier layer 11 and the silicon grains 13, the second dielectric layer 31 forms the dielectric of the capacitive structure, and conductive layer 41 forms the second electrode of the capacitive structure.

If the etching mask 50 has been left on the top surfaces of the mesa regions there is no grain structure in this region of the capacitive structure. This is illustrated in detail C of FIG. 2E. In the region of these top surfaces of the mesa regions second dielectric layer 31 directly adjoins carrier layer 11 and separates carrier layer 11 from conductive layer 41. In case the etching mask 50 has been omitted, then the structure in the region of the top surfaces of the mesa region corresponds to the structure on the bottom of the trenches which is illustrated in detail B.

The capacitive structure that has been explained above may be used in any device or semiconductor component in which integrated capacitor structures are required. These semiconductor components include storage devices, like DRAMs.

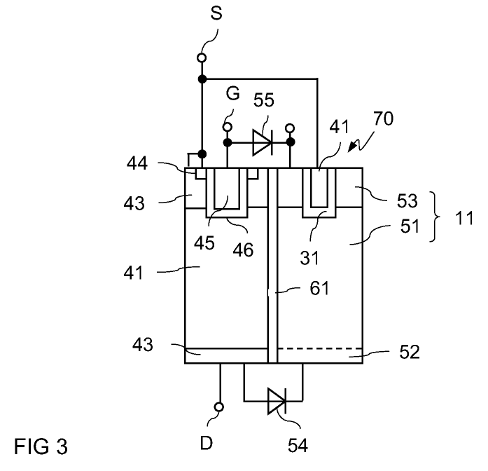

Referring to FIG. 3 the capacitive structure may also be used in a special kind of power semiconductor component that is known as TEDFET (Trench Extended Drain Field Effect Transistor). One example of such power semiconductor component is illustrated in FIG. 3. This component includes a conventional MOS transistor structure having a drift zone 41 being arranged between a drain zone 42 and a body zone 43, with body zone 43 being arranged between drift zone 41 and a source zone 44. The MOS transistor structure further includes a gate electrode 45 that is arranged adjacent to body zone 43 and that is separated from body zone 43 by a gate dielectric 46. Gate electrode 45 extends in the body zone 43—separated by the gate dielectric 46—from source zone 44 to drift zone 41 and serves to control a conducting channel in the body zone 43 between source zone 44 and drift zone 41. In the embodiment illustrated in FIG. 3 the MOS transistor structure is a vertical trench transistor structure in which the gate electrode 45 is arranged in a trench that extends in a vertical direction of a semiconductor body 100 in which the MOS transistor structure is integrated. However, this is only one embodiment. The MOS transistor structure may as well be realized to have a planar gate electrode.

Besides a vertical transistor structure, in which a drift zone extends in a vertical direction of the semiconductor body, the principle that will be explained in the following does also apply to lateral transistor structures.

The MOS transistor structure may be an n-type or a p-type transistor structure. In an n-type transistor structure source zone 44 and drain zone 42 are n-doped and body zone 43 is p-doped. In a p-typed transistor structure the doping types of these component zones are inverted.

Further, source terminal S contacts both, source zone 44 and body zone 43, as in usual MOS transistors.

Besides the MOS transistor structure the power semiconductor component includes a drift control zone 51 that is arranged adjacent to drift zone 41 and that is separated from drift zone 41 by a drift control zone dielectric 61. The function of the drift control zone 51 is to control a conducting channel in the drift zone 41 along drift control zone dielectric 61 if the MOS transistor structure is in its on-state. Drift control zone 51 therefore serves to reduce the on-resistance of the overall transistor component.

Unlike usual MOS transistors drift zone 41 in this semiconductor component, disregarding of the type of the MOS transistor structure, may be n-doped or p-doped. If, for example, in an n-type MOS transistor structure drift zone 41 is n-doped, then an accumulation channel is formed along drift control zone dielectric 61 and controlled by drift control zone 51. If in an n-type MOS transistor structure drift zone 41 is p-doped, then an inversion channel forms along drift control zone dielectric 61 in the drift zone 41, if the component is in its on-state. Like a usual MOS transistor this component is in its on-state if a voltage is applied between source and drain zones 44, 42 or source and drain terminals S, D, respectively, and if a suitable electrical potential is applied to gate electrode 45 that effects a conducting channel in the body zone 43 between source zone 44 and drift zone 41. In an n-type MOS transistor structure the voltage to be applied between drain D and source S in order to put the component in its on-state is a positive voltage, and the gate potential is a positive potential as compared to source potential.

If the transistor component is in its on-state charge carriers are required in the drift control zone 51 to effect the accumulation or inversion channel along drift control zone dielectric 61 in the drift zone 41. In a transistor component having an n-type MOS transistor structure, p-charge carriers (holes) are required in the drift control zone 51 for affecting this conducting channel. These charge carriers in the drift control zone 51 are only required, if the component is in its on-state. If the component is in its blocking state, these charge carriers are removed from drift control zone 51 and—equivalently to drift zone 41—a space charge zone or depletion zone forms in drift control zone 51. In this connection it should be mentioned that drift control zone 51 may be of the same conduction type as drift zone 41 or may be of a complementary conduction type.

Drift control zone 51 is coupled via a rectifying element 54, like, for example, a diode, to drain zone 42. The rectifying element is polarized such that discharging of the drift control zone 51 to the electrical potential of drain zone 42 is prevented, if the component is in its on-state. In an n-type transistor component an anode terminal of rectifying element 54 is coupled to drift control zone 51, while a cathode terminal is connected to drain zone 42. A second connection terminal 52 that is arranged between drift control zone 51 and the rectifying element 54 is optional and is of the same conduction type as drift control region 51, but more highly doped.

The charge carriers that are moved from drift control zone 51, if the component blocks, are stored in a capacitive structure 70 until the component is switched on for the next time, the capacitive structure being connected between source S and drift control zone 51. At switching on of the component the charge carriers stored in the capacitive structure 70 are “shifted” into drift control zone 51.

The capacitive structure 70 is an integrated capacitive structure that is produced in accordance with the method that has been explained above. This capacitor structure 70 is formed in a connection zone 53 that adjoins the drift control zone 51 and that is p-doped in an n-type component. Further, the capacitive structure 70 can partly extend into the drift control zone 51. Connection zone 53 and drift control zone 51 act as the carrier layer or first electrode of the capacitive structure.

For providing charge carriers to the drift control zone 51, if the component is switched on for the first time, i.e., if the capacitive structure 70 has not been charged, yet, drift control zone 51 may be coupled to gate terminal G via the first connection zone 53. In this case charge carriers are provided from a gate driver circuit that, in operation of the transistor component, is coupled to the gate terminal G. A diode 55 that is coupled between gate terminal G and the connection zone 53 serves to prevent discharging the drift control zone 51 in the direction of the gate terminal G.

It should further be noted that features that have been explained in connection with one example may be combined with features of other examples even in those cases in which this is not explicitly been mentioned.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method for producing a device including a capacitive structure, comprising:
providing a carrier layer having a surface;
forming a first dielectric layer on the surface;
forming a silicon layer including silicon grains on the first dielectric layer using a deposition process;
forming a second dielectric layer on the silicon layer;
forming a layer of an electrically conductive material on the dielectric layer; and
performing a temperature process for heating at least the first dielectric layer, temperature and duration of the temperature process being selected such that the first dielectric layer being modified so that the silicon layer is electrically connected to the carrier layer.

2. The method of claim 1, comprising wherein the carrier layer is a silicon layer.

3. The method of claim 1, comprising wherein the first dielectric layer contains at least of an oxide and a nitride.

4. The method of claim 1, comprising wherein a thickness of the first dielectric layer is less than 5 nm.

5. The method of claim 4, comprising wherein a thickness of the first dielectric layer is less than 3 nm, less than 1 nm or less than 0.5 nm.

6. The method of claim 1, comprising wherein a temperature of the temperature process is between 700° C. and 1300° C., and in which a duration of the temperature process is between 0.5 minutes and 800 minutes.

7. The method of claim 1, comprising producing the silicon grains to have a diameter of more than 40 nm.

8. The method of claim 1, comprising producing the silicon grains to have a diameter of more than 70 nm.

9. The method of claim 1, comprising wherein the electrically conductive material is doped polysilicon.

10. The method of claim 1, comprising wherein the first silicon layer is a silicon substrate.

11. A method for producing a device including a capacitive structure comprising:
providing a carrier layer having a surface;
forming a first dielectric layer on the surface;
forming a silicon layer including silicon grains on the first dielectric layer using a deposition process;
forming a second dielectric layer on the silicon layer;
forming a layer of an electrically conductive material on the dielectric layer; and
performing a temperature process for heating at least the first dielectric layer, temperature and duration of the temperature process being selected such that the first dielectric layer being modified so that the silicon layer is electrically connected to the carrier layer,
wherein the deposition process involves depositing silicon from a gaseous silicon source in a process chamber under pressure.

12. The method of claim 11, comprising wherein the gaseous silicon source includes chlorine.

13. The method of claim 12, comprising wherein the gaseous silicon source is dichlorosilane, trichlorosilane or silicontetrachloride.

14. The method of claim 11, comprising wherein deposition of silicon from the gaseous silicon source takes place in the presence of an etching gas in the process chamber.

15. The method of claim 14, comprising wherein the etching gas is hydrogen chloride gas.

16. The method of claim 13, comprising wherein the gas flow of the dichlorosilane gas is between 0.01 slpm and 1 slpm.

17. The method of claim 16, comprising wherein the pressure in the process chamber is between 1 Torr and 100 Torr.

18. The method of claim 15, comprising wherein the gas flow of the hydrogen chloride gas is between 0 and 0.5 slpm.

19. The method of claim 13, comprising wherein the gas flow of the trichlorosilane gas is between 0.1 slpm and 10 slpm.

20. The method of claim 19, comprising wherein the pressure in the process chamber is atmospheric pressure.

21. The method of claim 19, comprising wherein the gas flow of the hydrogen chloride gas is between 0 and 5 slpm.

22. The method of claim 11, comprising wherein a temperature during the deposition process is between 600° C. and 1250° C.

23. A method for producing a device including a capacitive structure comprising:
providing a carrier layer having a surface;
forming a first dielectric layer on the surface;
forming a silicon layer including silicon grains on the first dielectric layer using a deposition process;
forming a second dielectric layer on the silicon layer;
forming a layer of an electrically conductive material on the dielectric layer; and
performing a temperature process for heating at least the first dielectric layer, temperature and duration of the temperature process being selected such that the first dielectric layer being modified so that the silicon layer is electrically connected to the carrier layer; and
forming at least one trench in the first silicon layer, the surface at least partly being a surface of the at least one trench.

24. The method of claim 23, further comprising:
forming a protection layer on the first silicon layer before forming the at least one trench.

25. A method for making a power semiconductor device comprising:
forming a first dielectric layer on a carrier;
forming a silicon layer including silicon grains on the first dielectric layer;
forming a second dielectric layer on the silicon layer;
applying a temperature process to modify at least the first dielectric layer, enabling a capacitive structure.
